(19) United States
(12) Patent Application Publication
(10) Pub. No.: US 2015/0212427 A1
(43) Pub. Date: Jul. 30, 2015

(54) MULTILAYER MIRROR STRUCTURE

(71) Applicant: National Taiwan University, Taipei (TW)

(72) Inventors: Jia-Han Li, Taipei (TW); Yen-Min Lee, Taipei (TW); Kuen-Yu Tsai, Taipei (TW)

(21) Appl. No.: 14/448,274

(22) Filed: Jul. 31, 2014

(30) Foreign Application Priority Data
Jan. 28, 2014 (TW) 103103092

(51) Int. Cl. G03F 7/20; G02B 5/08

(52) U.S. Cl. CPC G03F 7/70316; G02B 5/0891

(57) ABSTRACT

A multilayer mirror structure for reflecting extreme ultraviolet (EUV) light is provided. The multilayer mirror structure includes a substrate and a plurality of first material layers and a plurality of second material layers alternately stacked on the substrate. Each of the first material layers has a plurality of low loss regions defined thereon. Each of the low loss regions has a low loss member for reducing the loss of the EUV light when the low loss regions are irradiated with the EUV light, thereby enhancing the reflectivity of the first material layers.

### BACKGROUND OF THE INVENTION

1. Field of the Invention

The present invention relates to mirror structures, and, more particularly, to a multilayer mirror structure having an enhanced reflectivity.

2. Description of Related Art

In recent years, along with fine-pitch designs of semiconductor integrated circuits, projection exposure equipment has been developed. In order to improve the resolution of an optical system that is limited by light diffraction, light with a wavelength less than ultraviolet, such as extreme ultraviolet (EUV) light with a wavelength in the range of 11 to 14 nm or deep extreme ultraviolet (DEUV) light with a wavelength in the range of 5 to 8 nm, is usually used.

Generally, a multilayer film structure is provided by alternately forming molybdenum (Mo) and silicon (Si) or niobium (Nb) and silicon (Si) on a substrate through deposition or evaporation. When the Bragg condition is satisfied, reflection waves undergo constructive interferences, thus leading to a high reflectivity. Therefore, such a structure can be used as a mirror.

The wavelength of EUV light is much less than that of visible light and very close to that of X-ray. Since EUV radiation can be absorbed by almost every material, conventional systems having transmission covers and transmission optical elements such as lenses cannot be used. Instead, EUV radiation is reflected or focused by a mirror optical element having a high reflectivity. The mirror optical element is further shaped to guide EUV radiation to a wafer to be patterned.

Therefore, an EUV mirror is required to have a surface with a high reflectivity and be capable of keeping its shape under high heat. To meet the requirements, a multilayer system is applied to a substrate having very low thermal expansion. Generally, 40 molybdenum layers and 40 silicon layers are alternately deposited on a substrate. Each of the molybdenum layers and the silicon layers has a thickness in nano-scale. At the interface between adjacent molybdenum and silicon layers, a portion of radiation is reflected. Theoretically, more than 70% of the incident radiation is reflected. However, since EUV radiation can be absorbed by almost every material, the reflectivity of 70% is only a theoretical value and cannot be reached in reality.

Therefore, how to overcome the above-described drawbacks has become critical.

### SUMMARY OF THE INVENTION

In view of the above-described drawbacks, the present invention provides a multilayer mirror structure for reflecting EUV (Extreme Ultraviolet) light, which comprises: a substrate; and a plurality of first material layers and a plurality of second material layers alternately stacked on the substrate, wherein each of the first material layers has a plurality of low loss regions each having a low loss member for reducing the loss of the EUV light when the low loss regions are irradiated with the EUV light. In an embodiment, the low loss member is in a form of a through hole penetrating the corresponding first material layer.

In another embodiment, the low loss member is embedded in the corresponding first material layer.

According to the present invention, since each of the first material layers has a plurality of low loss regions each having a low loss member, when the first material layers are irradiated with the EUV light, the low loss members can effectively reduce the loss of the EUV light so as to enhance the reflectivity of the first material layers.

### BRIEF DESCRIPTION OF DRAWINGS

FIG. 1 is a schematic view of a multilayer mirror structure according to the present invention;

FIG. 2 is a schematic upper view of a first material according to the present invention;

FIG. 3 is a schematic cross-sectional view taken along a sectional line A-A of FIG. 1;

FIG. 4 is a schematic cross-sectional view showing irradiation of EUV light on the multilayer mirror structure according to the present invention; and

FIG. 5 is a schematic upper view of the first material according to another embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

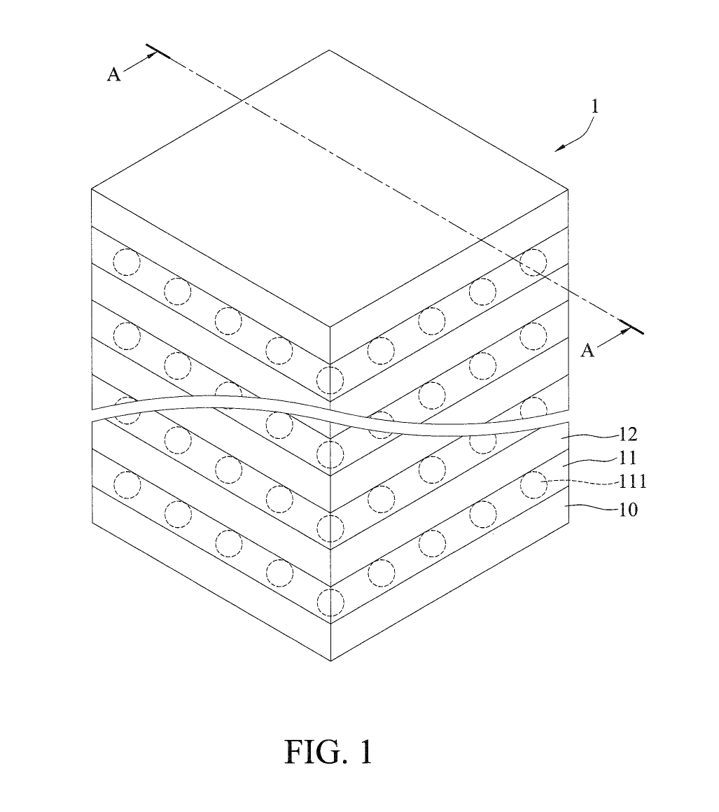

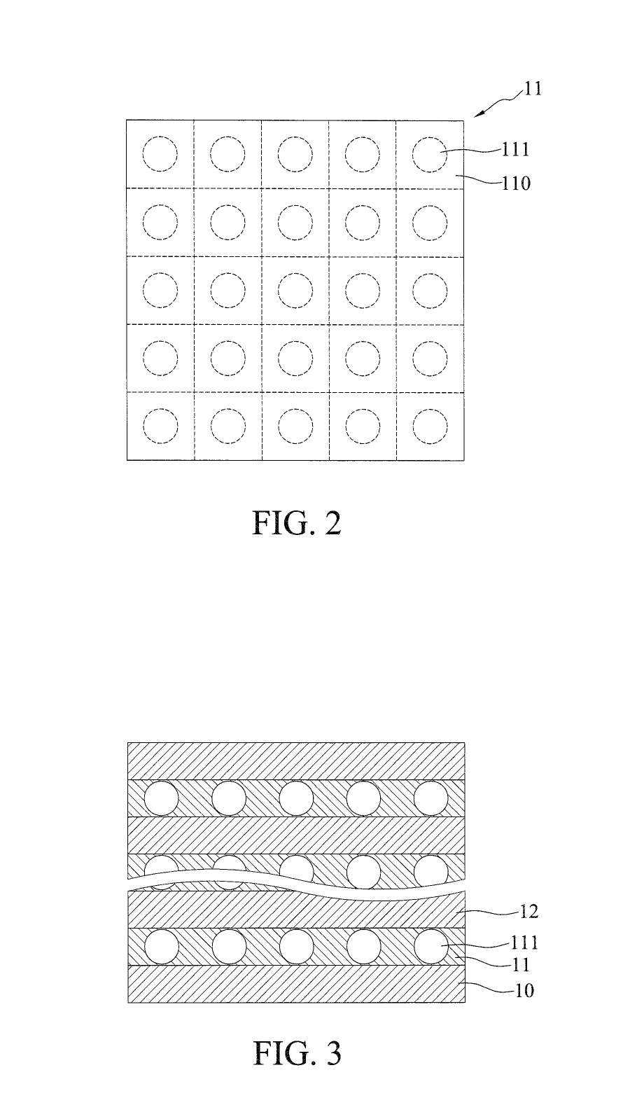

FIG. 1 is a schematic view of a multilayer mirror structure according to the present invention. FIG. 2 is a schematic upper view of a first material according to the present invention. FIG. 3 is a schematic cross-sectional view taken along a sectional line A-A of FIG. 1.

Referring to FIGS. 1 to 3, the multilayer mirror structure 1 has a substrate 10 and a plurality of first material layers 11 and a plurality of second material layers 12 alternately stacked on the substrate 10. The first material layers 11 are silicon layers, and the second material layers 12 are molybdenum layers. In the present invention, the multilayer mirror structure 1 has 40 first material layers 11 and 40 second material layers 12.

Referring to FIG. 2, each of the first material layers 11 has a plurality of low loss regions 110, and each of the low loss regions 110 has a low loss member 111 for reducing the loss of EUV light.

It should be noted that a plurality of dashed lines shown in FIG. 2 are used to help define the low loss regions 110 of the first material layer 11. In practice, only a plurality of low loss members 111 are regularly or irregularly embedded in the first material layer 11, and there are no dashed lines on the first material layer 11.

Referring to FIGS. 1 and 3, in the present embodiment, the low loss members 111 of the first material layers 11 can be made of a solid-state or gas-state material. For convenience purposes, the low loss members 111 made of a gas-state material are shown in the drawings.

In the present embodiment, the gas-state material is embedded in the first material layers 11 to form bubbles, i.e., the low loss members 111. Compared with the first material layers 11 made of silicon, the low loss members 111 have a lower EUV absorption rate and therefore achieve a better reflection effect, thereby enhancing the EUV reflectivity of the first material layers 11.

In the present embodiment, the gas-state material can be, but not limited to, helium, neon, argon, krypton, xenon, radon, fluorine, chlorine, hydrogen, oxygen or nitrogen. For example, the gas-state material can also be air or other gaseous substances.

In addition, the low loss members 111 can be made of a solid-state material such as strontium or beryllium, which is embedded in the first material layers 11 to enhance the EUV reflectivity of the first material layers 11.

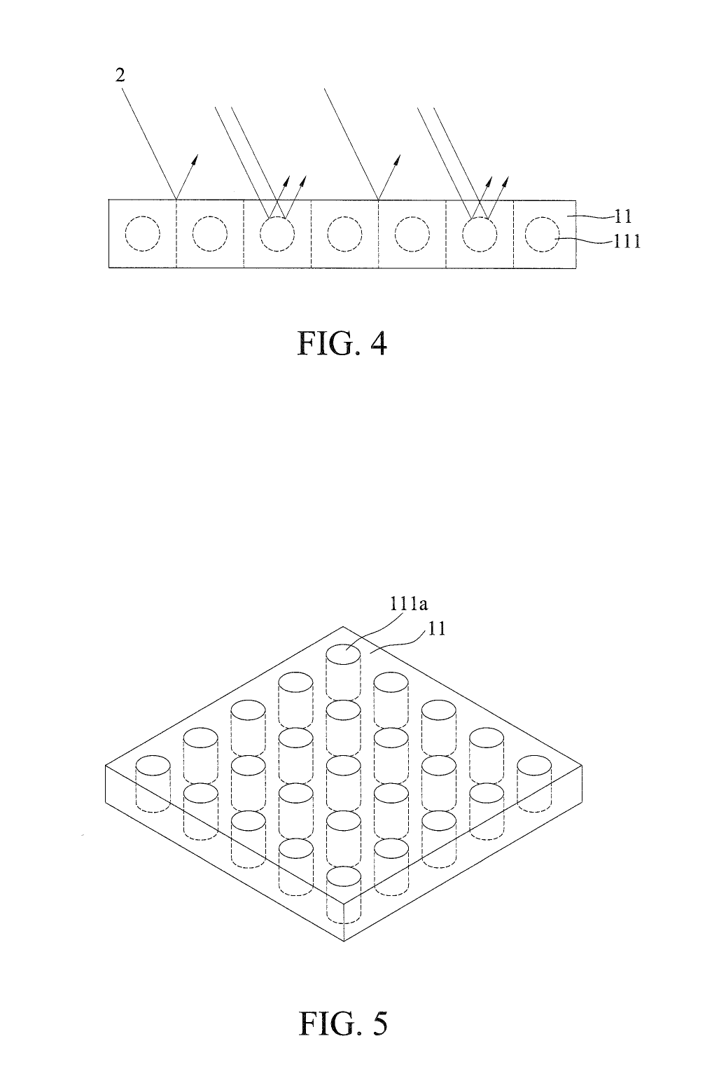

FIG. 4 shows irradiation of EUV light on the multilayer mirror structure according to the present invention. Referring to FIG. 4, since the low loss members 111 embedded in the first material layers 11 have an EUV absorption rate lower than that of the first material layers 11 made of silicon, when the first material layers 11 are irradiated with EUV light 2, a better reflection effect can be achieved by the low loss members 111, as compared with the first material layers 11.

FIG. 5 is a schematic upper view of the first material according to another embodiment of the present invention. Referring to FIG. 5, the present embodiment differs from the previous embodiment in that the low loss members 111a of each of the first material layers 11 are in the form of through holes that penetrate the first material layer 11.

Referring to FIGS. 5 and 1, the low loss members 111a in the form of through holes allow the EUV light 2 to penetrate therethrough, thereby reducing the EUV absorption rate of the first material layers 11 and enhancing the reflectivity of the first material layers 11.

In the present embodiment, the through holes are of a circular shape and regularly arranged. In other embodiments, the through holes can be of a rectangular shape or a hexagonal shape. Further, the through holes can be regularly or irregularly arranged.

It should be noted that the shape, size and arrangement of the low loss members 111, 111a are not limited to the above-described embodiments. For example, the size or number of the low loss members 111, 111a can be increased as long as they do not adversely affect the structural strength of the first material layers 11.

According to the present invention, a plurality of low loss members 111, 111a are embedded in the first material layers 11 or in the form of through holes penetrating the first material layers 11 so as to reduce the EUV absorption rate of the first material layers 11, thereby enhancing the reflection effect.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A multilayer mirror structure for reflecting extreme ultraviolet (EUV) light, comprising:
a substrate; and
a plurality of first material layers and a plurality of second material layers alternately stacked on the substrate, wherein each of the first material layers has a plurality of low loss regions each having a low loss member for reducing a loss of the EUV light when the low loss regions are irradiated with the EUV light.

2. The multilayer mirror structure of claim 1, wherein the first material layers are silicon layers, and the second material layers are molybdenum layers.

3. The multilayer mirror structure of claim 1, wherein the low loss member is in a form of a through hole penetrating the corresponding first material layer.

4. The multilayer mirror structure of claim 1, wherein the low loss members is embedded in the corresponding first material layer.

5. The multilayer mirror structure of claim 4, wherein the low loss members is made of a solid-state material.

6. The multilayer mirror structure of claim 5, wherein the solid-state material is strontium or beryllium.

7. The multilayer mirror structure of claim 4, wherein the low loss member is made of a gas-state material.

8. The multilayer mirror structure of claim 7, wherein the gas-state material is helium, neon, argon, krypton, xenon, radon, fluorine, chlorine, hydrogen, oxygen or nitrogen.
